(19) United States
(12) Patent Application Publication
(10) Pub. No.: US 2025/0311367 A1
(43) Pub. Date: Oct. 2, 2025

(54) SOURCE/DRAIN REGION WITH PROTECTIVE LINER LAYER

(71) Applicant: International Business Machines Corporation, Armonk, NY (US)

(72) Inventors: Ruilong Xie, Niskayuna, NY (US); Kisik Choi, Watervliet, NY (US); Chen Zhang, Santa Clara, CA (US); Shogo Mochizuki, Mechanicville, NY (US)

(21) Appl. No.: 18/624,743

(22) Filed: Apr. 2, 2024

(51) Int. Cl. H01L 29/423; H01L 29/06; H01L 29/417; H01L 29/775; H01L 29/786

(52) U.S. Cl. CPC H10D 64/518; H10D 30/43; H10D 30/6735; H10D 30/6757; H10D 62/121; H10D 64/254; H10D 64/258

(57) ABSTRACT

A semiconductor structure includes a plurality of nanosheet channel layers, wherein the plurality of nanosheet channel layers define a channel region, a gate structure on the channel region, a source/drain liner layer disposed on sidewalls of the plurality of nanosheet channel layers and the gate structure, a source/drain region disposed on the source/drain liner layer, wherein a bottom portion of the source/drain region extends into a backside interlevel dielectric layer and a backside contact connected to the bottom portion of the source/drain region. The bottom portion of the source/drain region is isolated from the gate structure by the source/drain liner layer and a protecting liner layer arranged between the gate structure and the bottom portion of the source/drain region.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure includes a plurality of nanosheet channel layers, wherein the plurality of nanosheet channel layers define a channel region, a gate structure on the channel region, a source/drain liner layer disposed on sidewalls of the plurality of nanosheet channel layers and the gate structure, a source/drain region disposed on the source/drain liner layer. A bottom portion of the source/drain region extends into a backside interlevel dielectric layer, and a backside contact connected to the bottom portion of the source/drain region. The bottom portion of the source/drain region is isolated from the gate structure by the source/drain liner layer and a protecting liner layer arranged between the gate structure and the bottom portion of the source/drain region.

In an illustrative embodiment, a semiconductor structure includes a plurality of nanosheet channel layers, wherein the plurality of nanosheet channel layers define a channel region, a gate structure on the channel region, a source/drain liner layer disposed on sidewalls of the plurality of nanosheet channel layers and the gate structure, a source/drain region disposed on the source/drain liner layer, and a backside contact connected to a bottom portion of the source/drain region. The bottom portion of the source/drain region is isolated from the gate structure by the source/drain liner layer and a protecting liner layer arranged between the gate structure and the source/drain liner layer.

In yet another illustrative embodiment, a semiconductor structure includes a first nanosheet device including a first gate structure on a first channel region, and a first source/drain liner layer disposed on sidewalls of the first gate structure. The semiconductor structure further includes a second nanosheet device adjacent the first nanosheet device. The second nanosheet device includes a second gate structure on a second channel region, and a second source/drain liner layer disposed on sidewalls of the second gate structure. The semiconductor structure further includes a source/drain region disposed between opposing sidewalls of the first source/drain liner layer and the second source/drain liner layer, and a backside contact connected to a bottom portion of the source/drain region. The bottom portion of the source/drain region is isolated from the first gate structure by the first source/drain liner layer and a first protecting liner layer arranged between the first gate structure and the first source/drain liner layer. The bottom portion of the source/drain region is isolated from the second gate structure by the second source/drain liner layer and a second protecting liner layer arranged between the second gate structure and the second source/drain liner layer.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 depicts a cross-sectional view illustrating a semiconductor structure during an intermediate step of a method of fabricating a nanosheet transistor structure, according to an illustrative embodiment.

FIGS. 2A-2B are cross-sectional views of the semiconductor structure following nanosheet patterning, followed by formation of a shallow trench isolation layer, according to an illustrative embodiment.

FIGS. 3A-3B are cross-sectional views of the semiconductor structure following formation of dummy gates and sidewall spacers, according to an illustrative embodiment.

FIGS. 4A-4B are cross-sectional views of the semiconductor structure following nanosheet recess, according to an illustrative embodiment.

FIGS. 5A-5B are cross-sectional views of the semiconductor structure following formation of a protecting liner layer and silicon recess, according to an illustrative embodiment.

FIGS. 6A-6B are cross-sectional view of the semiconductor structure following formation of a sacrificial placeholder layer, according to an illustrative embodiment.

FIG. 7A-7B are cross-sectional views of the semiconductor structure following removal of the exposed protecting liner layer, according to an illustrative embodiment.

FIGS. 8A-8B are cross-sectional views of the semiconductor structure following nanosheet sidewall recessing, according to an illustrative embodiment.

FIGS. 9A-9B are cross-sectional views of the semiconductor structure following formation of a source/drain liner layer and a source/drain region, according to an illustrative embodiment.

FIGS. 10A-10B are cross-sectional views of the semiconductor structure following formation of an interlayer dielectric (ILD) layer, removal of a hardmask layer, dummy gates and sacrificial layers and formation of a replacement metal gate, according to an illustrative embodiment.

FIGS. 11A-11B are cross-sectional views of the semiconductor structure following formation of source/drain contacts, followed by formation of a frontside back-end-of-the-line interconnect and carrier wafer bonding, according to an illustrative embodiment.

FIGS. 12A-12B are cross-sectional views of the semiconductor structure following backside processing with removal of the substrate, according to an illustrative embodiment.

FIGS. 13A-13B are cross-sectional views of the semiconductor structure following removal of an etch stop layer and a semiconductor layer, according to an illustrative embodiment.

FIGS. 14A-14B are cross-sectional views of the semiconductor structure following formation of a backside ILD layer, according to an illustrative embodiment.

FIGS. 15A-15B are cross-sectional views of the semiconductor structure following formation of a backside contact opening, according to an illustrative embodiment.

FIGS. 16A-16B are cross-sectional views of the semiconductor structure following removal of the sacrificial placeholder layer, a bottom surface of source/drain liner layer and a portion of the source/drain region, according to an illustrative embodiment.

FIGS. 17A-17B are cross-sectional views of the semiconductor structure following formation of a backside source/drain metal contact and a backside interconnect, according to an illustrative embodiment.

FIGS. 18A-18B are cross-sectional views of the semiconductor structure starting from FIGS. 5A and 5B following formation of the sacrificial placeholder layer, according to an illustrative alternative embodiment.

FIGS. 19A-19B are cross-sectional views of the semiconductor structure following frontside processing, according to an illustrative alternative embodiment.

FIGS. 20A-20B are cross-sectional views of the semiconductor structure following backside processing, according to an illustrative alternative embodiment.

### DETAILED DESCRIPTION

This disclosure relates generally to semiconductor devices, and more particularly to semiconductor structures having a source/drain region with a protective liner layer, and methods for their fabrication. However, it is to be understood that embodiments of the present disclosure are not limited to the illustrative methods, apparatus, systems and devices but instead are more broadly applicable to other suitable methods, apparatus, systems and devices.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s). Other suitable techniques, such as sidewall image transfer (SIT), self-aligned double patterning (SADP), self-aligned quadruple patterning (SAQP), self-aligned multiple patterning (SAMP) can be used to etch or pattern.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL. The conductive contacts of the MOL layer provide electrical connections between the integrated circuitry of the FEOL layer and a first level of metallization of a BEOL structure that is formed over the FEOL/MOL layers.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

In general, backside contact formation usually requires forming a placeholder material, such as SiGe to assist with the backside contact alignment with larger placement error. An inner spacer is typically used in nanosheet technology to isolate the sacrificial SiGe nanosheets from the placeholder material. However, the use of an inner spacer results in a loss of strains due to defects in the source/drain epi, which is not desired for performance applications. Thus, a solution is needed to form a nanosheet device without the use of an inner spacer, and is compatible with the backside contact formation.

Illustrative embodiments overcome the foregoing drawbacks by isolating a bottom portion of a source/drain region from a gate structure in a channel portion by a source/drain liner layer and a protecting liner layer arranged between a bottom portion of the gate structure, a bottom portion of the source/drain liner layer and a bottom portion of a source/drain region. In addition, this configuration separates the sacrificial SiGe nanosheet layers (between nanosheet channel layers) from the SiGe based placeholder, thereby preventing placeholder damage during removal of the sacrificial SiGe nanosheet layers during the replacement metal gate formation process.

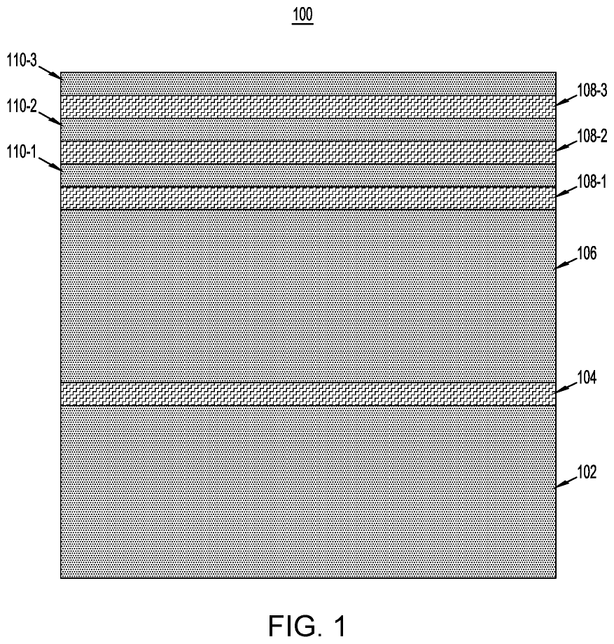

Referring now to the drawings in which like numerals represent the same or similar elements, FIGS. 1-20B illustrate various processes for fabricating semiconductor structures with a MOL contact. Note that the same reference numeral (100) is used to denote the semiconductor structure through the various intermediate fabrication stages illustrated in FIGS. 1-20B. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1-20B are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIGS. 1-17B show a semiconductor structure 100 in accordance with an illustrative embodiment. Referring now to FIG. 1, the semiconductor structure 100 is shown during an intermediate step of a method of fabricating a nanosheet transistor structure having one or more nanosheet devices according to an embodiment of the invention. The semiconductor structure 100 includes a substrate 102 and an etch stop layer 104 formed in the substrate 102. The substrate 102 may be formed of any suitable semiconductor material, including various silicon-containing materials including but not limited to silicon (Si), silicon germanium (SiGe), and multi-layers thereof. Although silicon is the predominantly used semiconductor material in wafer fabrication, alternative semiconductor materials can be employed as additional layers, such as, but not limited to, SiGe, germanium (Ge), gallium arsenide (GaAs), gallium indium arsenide (InGaAs), cadmium telluride (CdTe), zinc selenide (ZnSe), etc. In one illustrative embodiment, the substrate 102 is silicon.

The etch stop layer 104 may include a buried oxide (BOX) layer or silicon germanium (SiGe), or another suitable material such as a III-V semiconductor epitaxial layer.

A semiconductor layer 106 is formed on the etch stop layer 104. The semiconductor material for the semiconductor layer 106 can be silicon that is grown on the etch stop layer 104 of a desired thickness. In an illustrative embodiment, the semiconductor material such as silicon can be grown on the etch stop layer 104 using conventional epitaxial growth techniques such as low-pressure chemical vapor deposition (LPCVD), so that an epitaxial film of good quality may be grown.

Nanosheets are formed over the semiconductor layer 106, where the nanosheets include sacrificial layers 108-1, 108-2 and 108-3 (collectively, sacrificial layers 108), and nanosheet channel layers 110-1, 110-2 and 110-3 (collectively, nanosheet channel layers 110).

The sacrificial layers 108 are illustratively formed of a sacrificial material, such that they may be etched or otherwise removed selectively. In some embodiments, the sacrificial layers 108 are formed of SiGe. For example, the sacrificial layers 106 may have a relatively higher percentage of Ge (e.g., 55% Ge) or a relatively lower percentage of Ge (e.g., 25% Ge).

The nanosheet channel layers 110 may be formed of Si or another suitable material (e.g., a material similar to that used for the substrate 102).

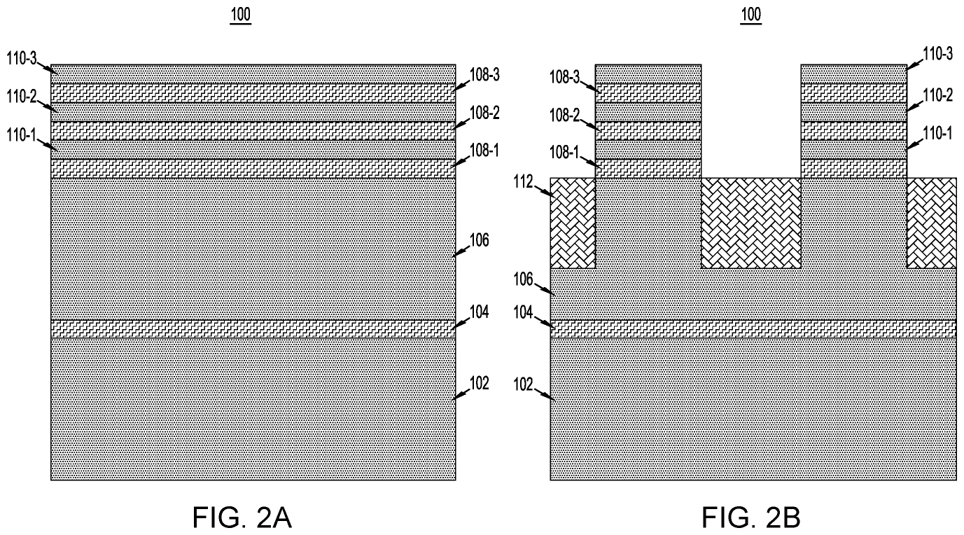

Referring now to FIGS. 2A and 2B, the semiconductor structure 100 is shown following nanosheet patterning and formation of shallow trench isolation (STI) regions, according to an embodiment of the invention. STI regions 112 may be formed by patterning a masking layer (not shown) over the semiconductor structure 100, followed by etching exposed portions of the nanosheet channel layers 110, the sacrificial layers 108, and through a portion of the semiconductor layer 106. The STI regions 112 may be formed of a dielectric material such as silicon dioxide (SiO₂), silicon oxycarbide (SiOC), silicon oxynitride (SiON), etc.

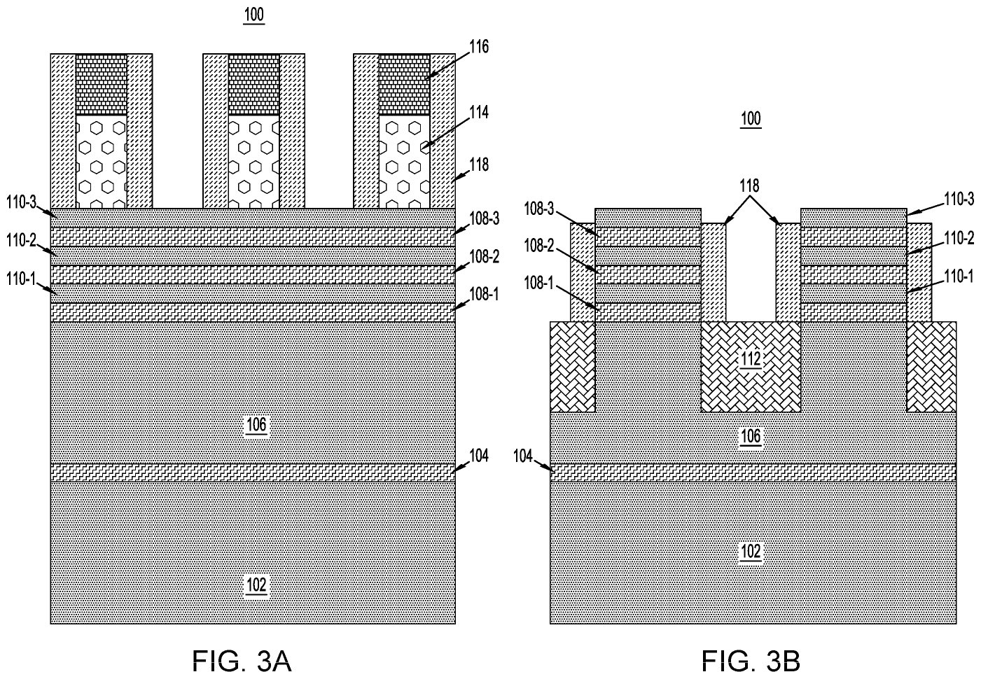

Referring now to FIGS. 3A and 3B, the semiconductor structure 100 is shown following formation of dummy gates, a hardmask layer and sidewall spacers, according to an embodiment of the invention. Dummy gates 114 and a hardmask layer 116 are first deposited on the topmost nanosheet channel layer 110-3 by conventional deposition techniques such as ALD, CVD, PVD, etc. Suitable dummy gate material includes, for example, polycrystalline silicon, amorphous silicon or microcrystal silicon. The hardmask layer 116 can be composed of a flowable organic material such as, for example, a spin-on-carbon (SOC), Si₃N₄, SiBCN, SiNC, SiN, SiCO, SiO₂, and SiNOC.

Sidewall spacers 118 are then formed on the dummy gates 114 and the hardmask layer 116 by conventional deposition techniques such as ALD, CVD, PVD, etc. The sidewall spacers 118 may be formed of any suitable insulator, such as SiN, SiBCN, SiCO, SiO₂ and silicon oxycarbonitride (SiOCN). In some exemplary embodiments, the sidewall spacers 118 can include a material that is resistant to some etching processes such as, for example, HF chemical etching or chemical oxide removal etching. FIG. 3B shows the sidewall spacers 118 formed on the sacrificial layers 108, the nanosheet channel layers 110-1 and 110-2 and on a portion of the nanosheet channel layer 110-3.

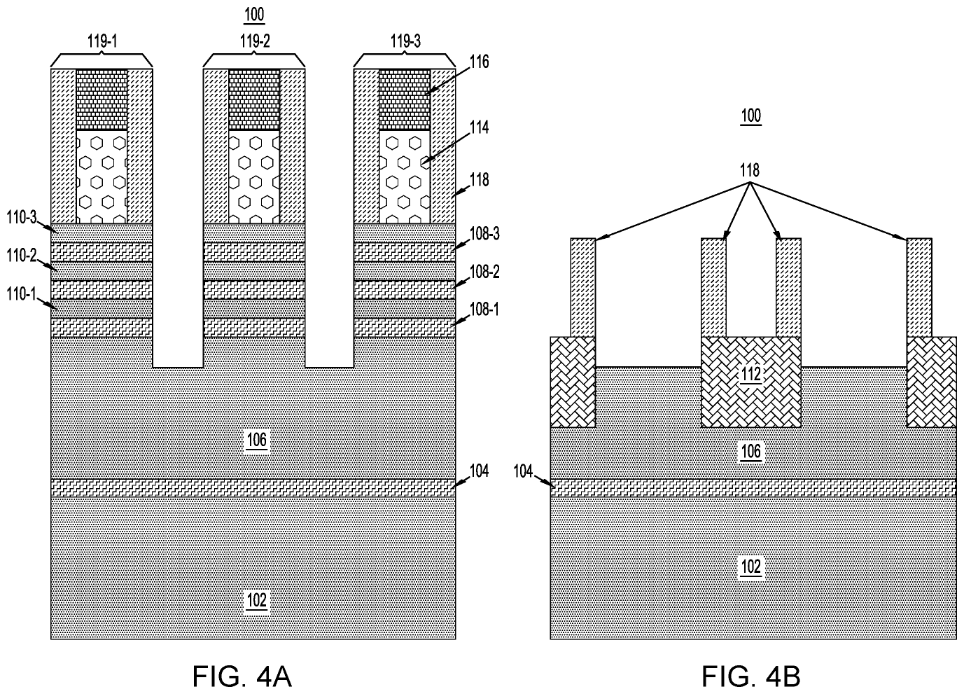

Referring now to FIGS. 4A and 4B, the semiconductor structure 100 is shown following formation of nanosheet devices, according to an embodiment of the invention. Nanosheet devices 119-1 to 119-3 are formed by etching exposed portions of the nanosheet channel layers 110 and the sacrificial layers 108 to expose the semiconductor layer 106. In some embodiments, the nanosheet devices 119-1 to 119-3 may include nFET devices and/or pFET devices. In addition, although three nanosheet devices are shown, this is merely illustrative and any number of nanosheet devices are contemplated.

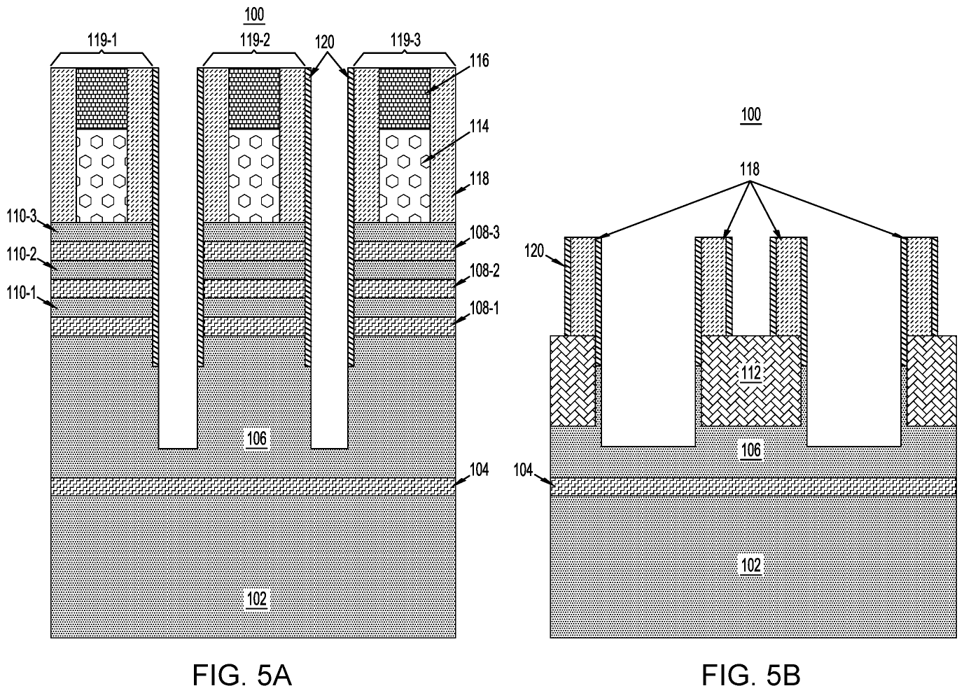

Referring now to FIGS. 5A and 5B, the semiconductor structure 100 is shown following formation of protecting liner layer and recess of the semiconductor layer 106, according to an embodiment of the invention. A protecting liner layer 120 is formed on sidewall of the nanosheet devices 119-1 to 119-3 by conventional deposition techniques such as ALD, CVD, PVD, etc. The protecting liner layer 120 may be formed of any suitable protecting material such as, for example, a nitride material such as SiN. Next, the semiconductor layer 106 is recessed using, for example, RIE.

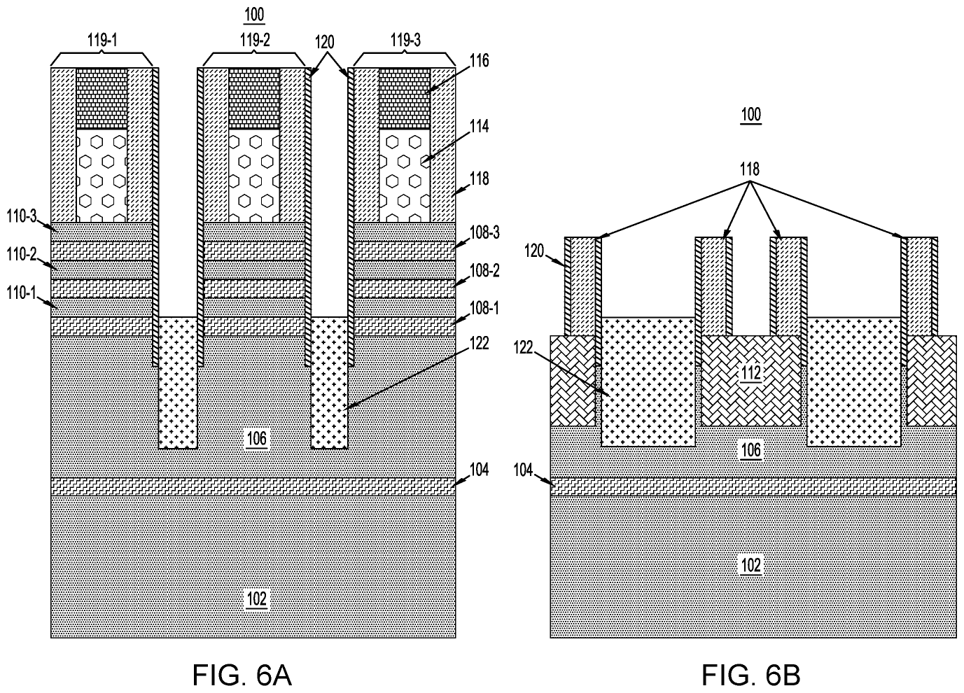

Referring now to FIGS. 6A and 6B, the semiconductor structure 100 is shown following formation of a sacrificial placeholder layer, according to an embodiment of the invention. A sacrificial placeholder layer 122 is formed in the recessed area of the semiconductor layer 106 and on a portion of the protecting liner layer 120 using conventional deposition techniques such as ALD, CVD, PVD, etc. The sacrificial placeholder layer 122 may be formed of a sacrificial material such as, for example, SiGe, titanium oxide (TiOₓ), aluminum oxide (AlOₓ), silicon carbide (SiC), etc. If the sacrificial placeholder layer 122 is formed from SiGe, then it can be formed by a bottom-up epitaxial growth process from bottom of the opening. FIG. 6A further shows that the sacrificial placeholder layer 122 is formed having a top surface at or about a top surface of the bottom-most sacrificial layer 108-1.

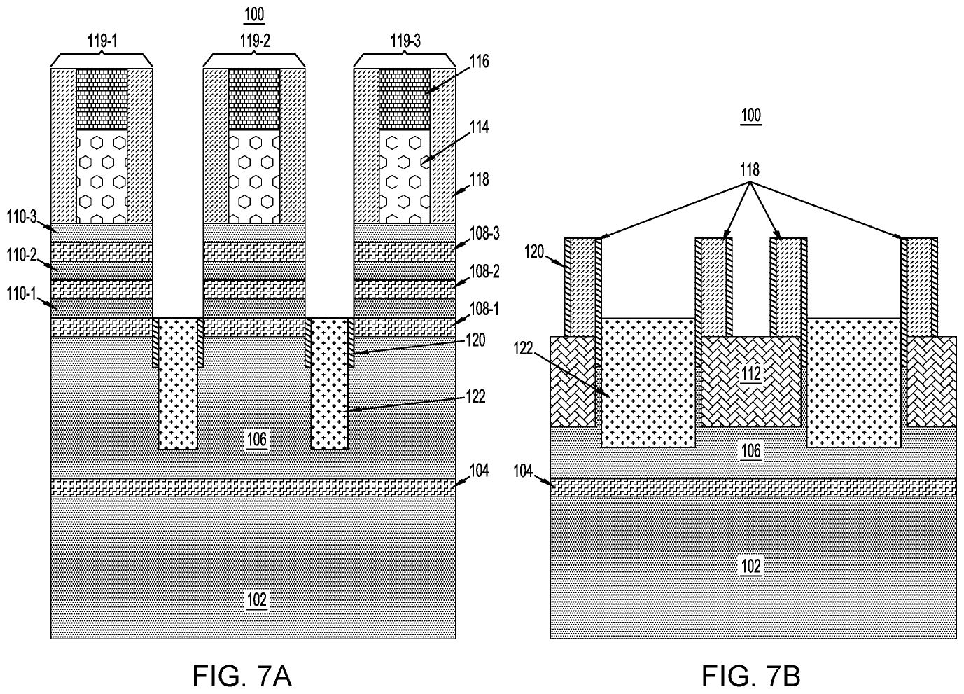

Referring now to FIGS. 7A and 7B, the semiconductor structure 100 is shown following removal of the exposed portion of the protecting liner layer 120, according to an embodiment of the invention. The protecting liner layer 120 exposed on sidewalls of the nanosheet devices 119-1 to 119-3 is removed using a conventional etching technique.

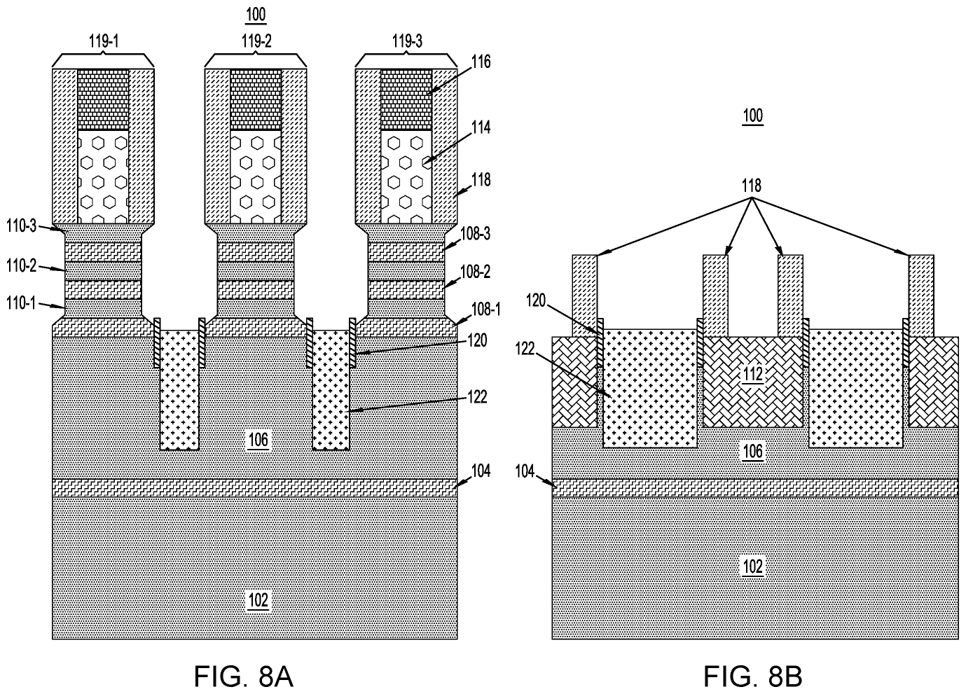

Referring now to FIGS. 8A and 8B, the semiconductor structure 100 is shown following trimming of the nanosheet channel layers 110 and the sacrificial layers 108, according to an embodiment of the invention. The exposed portions of the nanosheet channel layers 110 and the sacrificial layers 108 are trimmed to a desired thickness using a suitable chemical etching process such as, for example, a selective wet etch or dry etch process. FIG. 8A shows the middle portion including the nanosheet channel layers 110-1 and 110-2 and a portion of the nanosheet channel layer 110-3 along with the sacrificial layers 108-2 and 108-3 having a uniform length and the remaining portion of the top-most nanosheet channel layer 110-3 and the bottom-most sacrificial layer 108-1 having a tapered side.

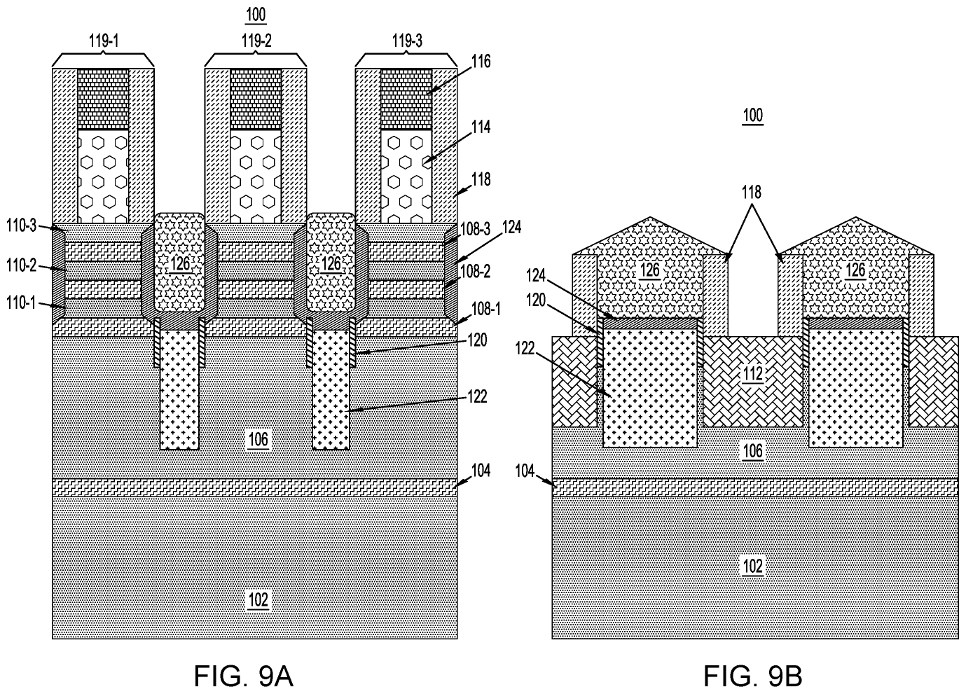

Referring now to FIGS. 9A and 9B, the semiconductor structure 100 is shown following formation of a source/drain liner layer and source/drain regions, according to an embodiment of the invention. FIG. 9A shows a source/drain liner layer 124 formed on the exposed portions of the sacrificial placeholder layer 122 and the protecting liner layer 120 and on the sidewalls of the nanosheet channel layers 110 and the sacrificial layers 108. Source/drain regions 126 are formed between opposing sidewalls of the source/drain liner layer 124 between adjacent nanosheet devices 119-1 to 119-3 and above a top surface of the top-most nanosheet channel layers 110-3. FIG. 9B shows the source/drain liner layer 124 formed on the exposed portion of the sacrificial placeholder layer 122 and the source/drain regions 126 formed between opposing sidewalls of the sidewall spacers 118.

The source/drain liner layer 124 can be formed from, for example, a silicon, using conventional epitaxial growth techniques such as LPCVD, so that an epitaxial film of good quality may be grown.

The source/drain regions 126 may be formed using epitaxial growth processes. The source/drain regions 126 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process includes in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain region can range from 1×10¹⁹ cm⁻³ to 3×10²¹ cm⁻³, or preferably between 2×10²⁰ cm⁻³ to 3×10²¹ cm⁻³.

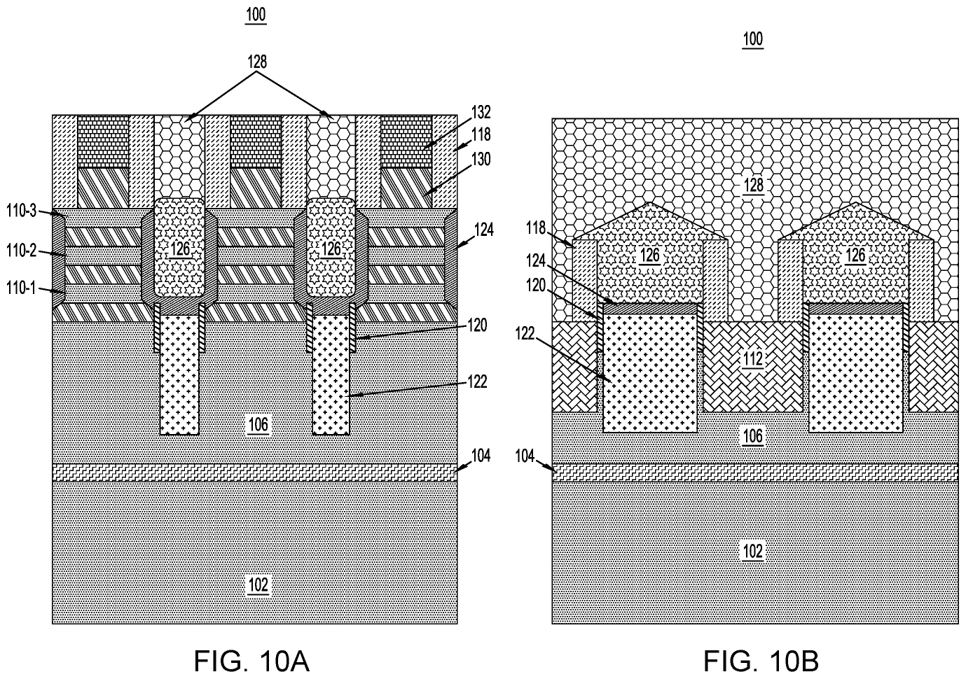

Referring now to FIGS. 10A and 10B, the semiconductor structure 100 is shown following formation of an interlevel dielectric (ILD) layer, a replacement gate structure and a gate cap, according to an embodiment of the invention. An ILD layer 128 is formed on the source/drain regions 126 and the STI regions 112, using conventional deposition techniques such as ALD, CVD, etc., followed by a planarization process such as CMP. The ILD layer 128 may be formed of any suitable isolating material, such as SiO₂, SiOC, SiON, etc. Next, the hardmask layer 116, the dummy gates 114 and the sacrificial layers 108 are removed using a selective etching process such as RIE or wet removal processes to thereby define a gate cavity where the replacement gate structure will subsequently be formed for the semiconductor structure 100. In addition, based on the source/drain liner layer 124, the source/drain regions 126 and the sacrificial placeholder layer 122 are well protected.

A replacement gate structure 130 is then formed using known replacement high-k metal gate (HKMG) processing operations. In some embodiments, the replacement gate structure 130 may include a gate dielectric layer and a gate conductor layer. The gate dielectric layer may be formed of a high-k dielectric material. Examples of high-k dielectric materials include, but are not limited to, metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg).

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

A dielectric gate cap 132 is then formed on the replacement gate structure 130 using any conventional deposition technique such as ALD, CVD, PVD, etc. The dielectric gate cap 132 may be formed of any suitable isolating material including various silicon-containing materials such as SiC and/or SiCO.

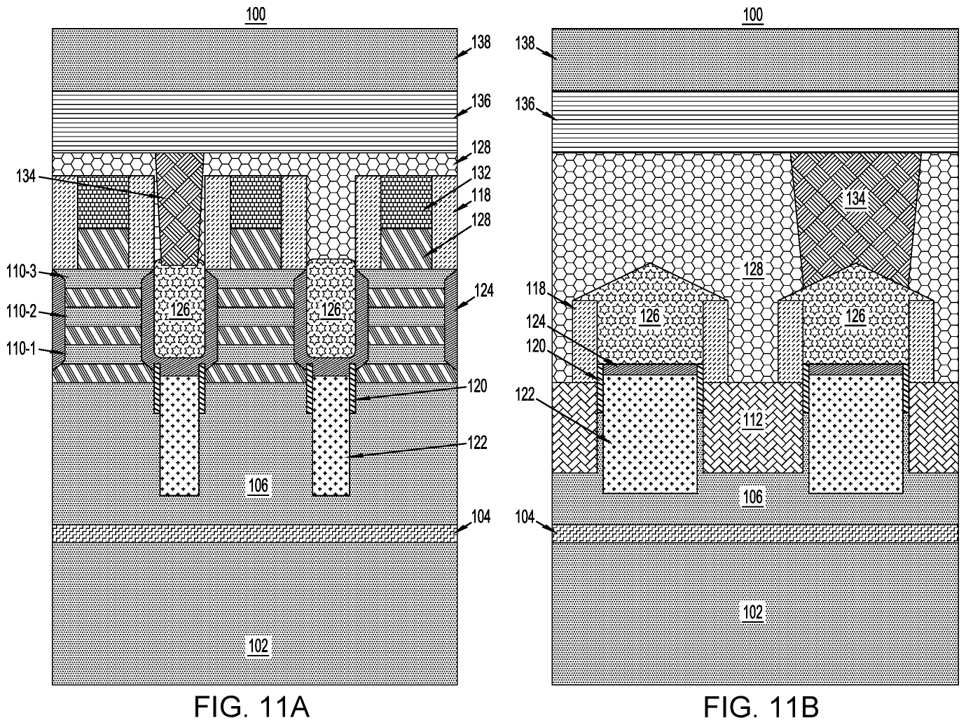

Referring now to FIGS. 11A and 11B, the semiconductor structure 100 is shown following the formation of middle-of-the-line contacts, a frontside back-end-of-line (BEOL) interconnect and a carrier wafer according to an embodiment of the invention. Middle-of-the-line contacts 134, which can also be referred to as frontside source/drain contacts 134, can be formed by any conventional technique. In some embodiments, the middle-of-the-line contacts 134 can be formed by depositing an additional amount of the ILD layer 128 and utilizing conventional lithographic and selective etch processes such as a wet or dry etch etching process in the ILD layer 128 to form an opening. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As another example, a wet etching process may include etching in DHF, potassium hydroxide (KOH) solution, ammonia, a solution containing hydrofluoric acid (HF), nitric acid (HNO₃), and/or acetic acid (CH₃COOH), or other suitable wet etchants.

Next, a high conductive metal is deposited in the opening to form the middle-of-the-line contacts 134. Suitable high conductive metals include, for example, a silicide liner such as Ti, Ni, NiPt, an adhesion metal liner such as TiN, followed by filling conductive material such as, for example, tungsten (W), aluminum (Al), copper (Cu), cobalt (Co), ruthenium (Ru), molybdenum (Mo), or any other suitable conductive material. In various embodiments, the high conductive metal can be deposited by ALD, CVD, PVD, and/or plating. The high conductive metal can be planarized using, for example, a planarizing process such as CMP. Other planarization processes can include grinding and polishing.

A frontside BEOL interconnect 136 is then formed followed by bonding of the structure (e.g., the frontside BEOL interconnect 136) to a carrier wafer 138. The frontside BEOL interconnect 136 includes various BEOL interconnect structures. For example, the frontside BEOL interconnect 136 is a metallization structure that includes one or more metal layers disposed on a side of the semiconductor structure 100 opposite of the side on which the backside BEOL metallization structure is disposed. The metal layers of the frontside BEOL interconnect 136 each have metal lines for making interconnections to the semiconductor device.

The carrier wafer 138 may be formed of materials similar to that of the substrate 102, and may be formed over the frontside BEOL interconnect 136 using a wafer bonding process, such as dielectric-to-dielectric bonding.

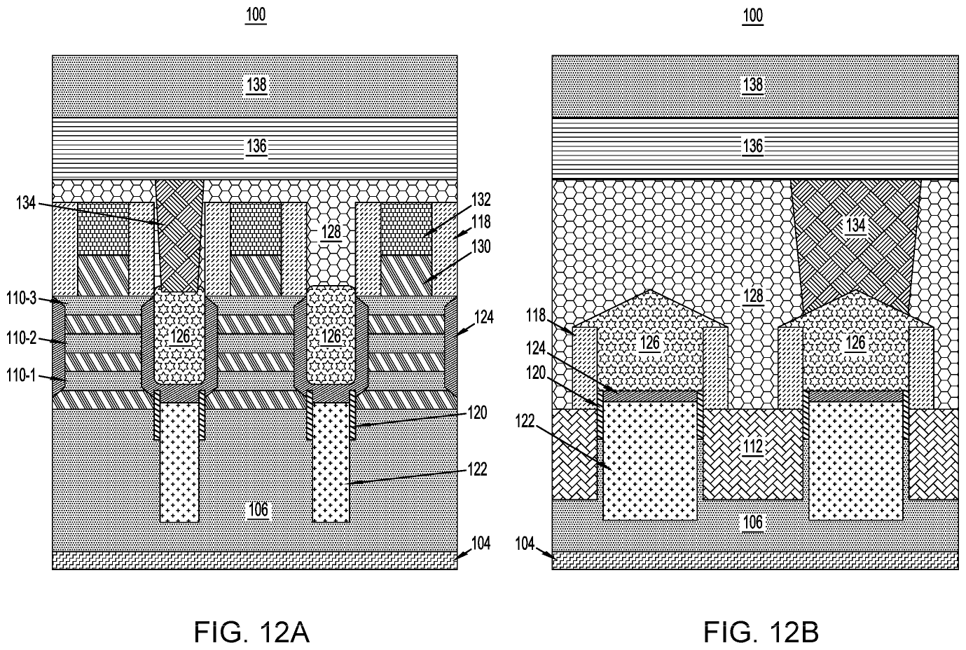

Referring now to FIGS. 12A and 12B, the semiconductor structure 100 is shown following backside processing of the substrate 102 according to an embodiment of the invention. The backside processing can be carried out by, for example, by flipping the semiconductor structure 100 over so that the backside of the substrate 102 (i.e., the back surface) is facing up. First, portions of the substrate 102 may be removed from the backside using, for example, a combination of wafer grinding, CMP, dry etch and/or wet etch to selectively remove the substrate 102 until the etch stop layer 104 is reached.

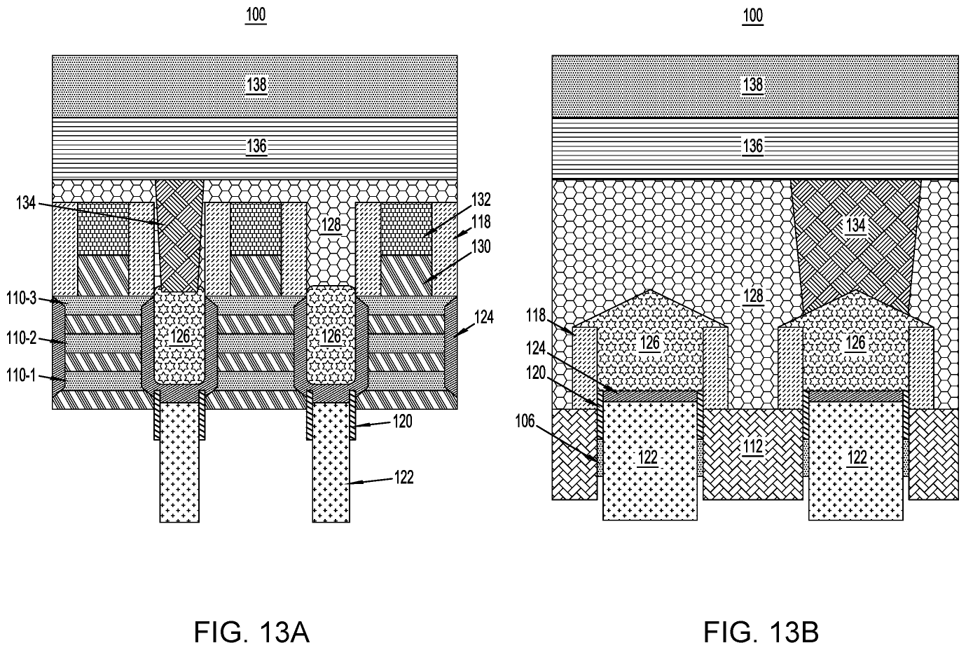

Referring now to FIGS. 13A and 13B, the semiconductor structure 100 is shown following removal of the etch stop layer 104 and the semiconductor layer 106, according to an embodiment of the invention. The etch stop layer 104 and the semiconductor layer 106 are selectively removed using, for example, a wet etch to selectively remove the etch stop layer 104 and the semiconductor layer 106. FIG. 13A shows the removal of the etch stop layer 104 and the semiconductor layer 106 until the replacement gate structure 130, the sacrificial placeholder layer 122, and a portion of the protecting liner layer 120 are reached. FIG. 13B shows the removal of the etch stop layer 104 and the semiconductor layer 106 until the sacrificial placeholder layer 122 and the STI regions 112 are reached. The protecting liner layer 120 protects the source/drain liner layer 124 from being damaged during the substrate removal process.

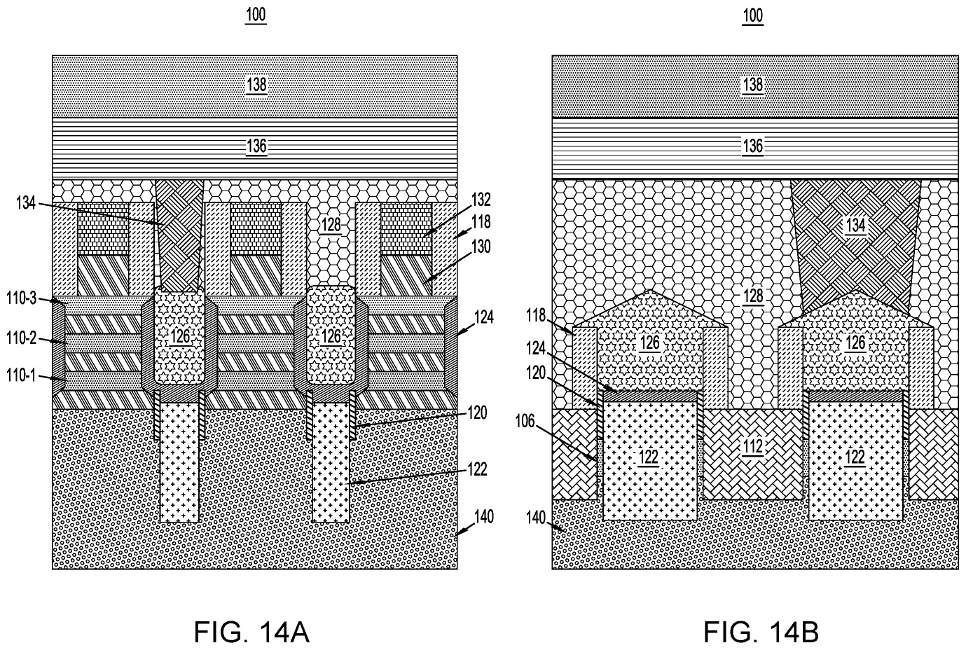

Referring now to FIGS. 14A and 14B, the semiconductor structure 100 is shown following the deposition of a backside ILD layer, according to an embodiment of the invention. A backside ILD layer 140 is deposited in the removed portions of the semiconductor layer 106. The backside ILD layer 140 may be formed of similar processes and material as the ILD layer 128. Following formation of the backside ILD layer 140, any overfill can be removed by a planarization process such as CMP.

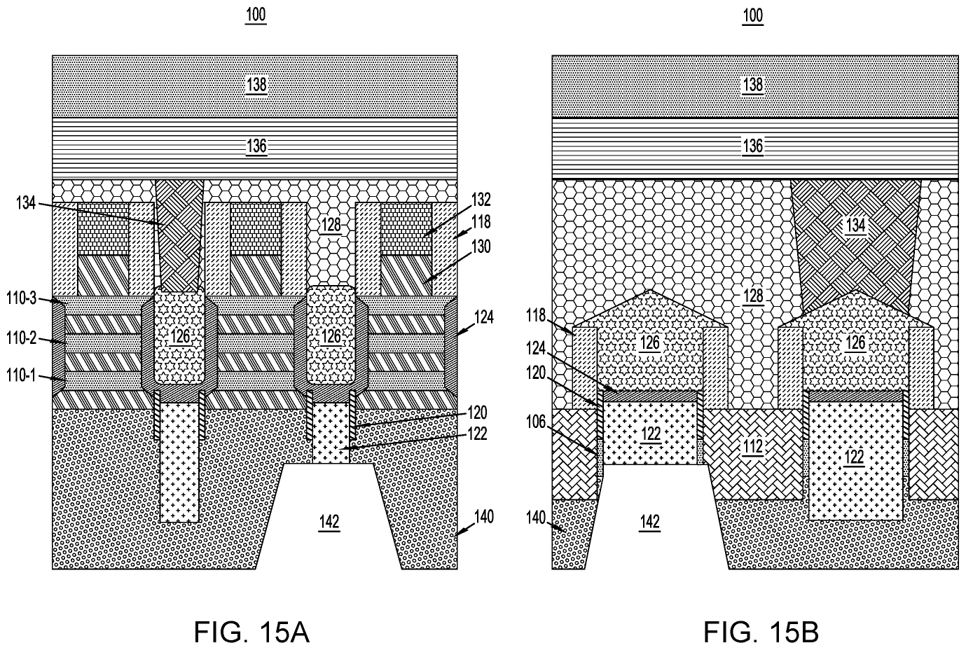

Referring now to FIGS. 15A and 15B, the semiconductor structure 100 is shown following the formation of backside middle-of-the-line contact openings, according to an embodiment of the invention. Backside middle-of-the-line contact openings 142a and 142b are formed in the backside ILD layer 140 to expose a bottom surface of the sacrificial placeholder layer 122 as shown in FIG. 15A and a bottom surface of the sacrificial placeholder layer 122 and the semiconductor layer 106 as shown in FIG. 15B. In some embodiments, the backside middle-of-the-line contact openings 142a and 142b can be formed by first patterning and etching lines in the backside ILD layer 140 using any suitable wet or dry etch.

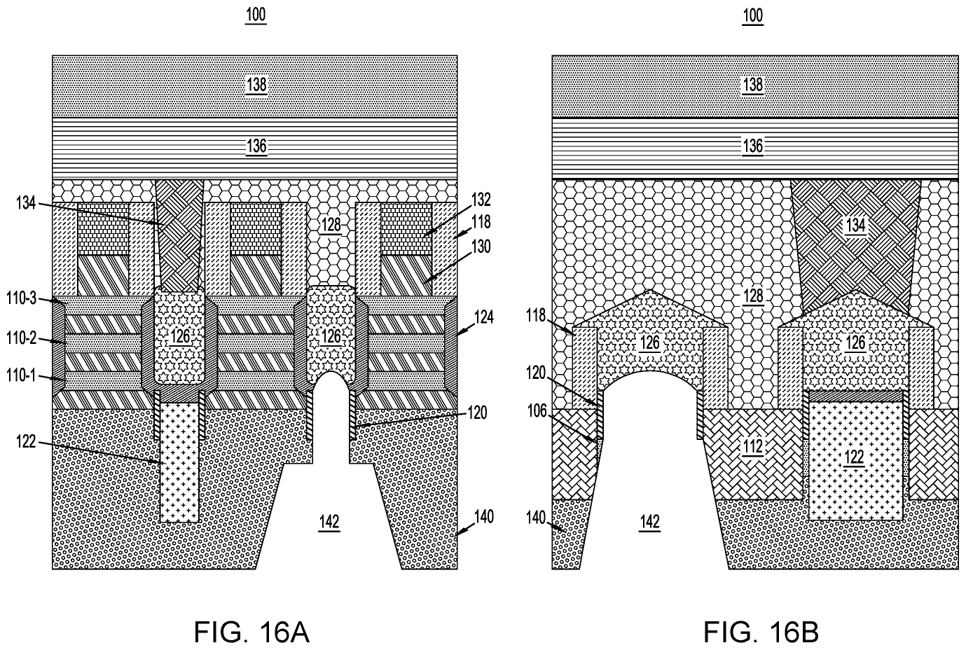

Referring now to FIGS. 16A and 16B, the semiconductor structure 100 is shown following removal of the sacrificial placeholder layer 122, the source/drain liner layer 124 and a portion of the source/drain regions 126, according to an embodiment of the invention. The sacrificial placeholder layer 122, the source/drain liner layer 124 and a portion of the source/drain regions 126 are removed using any suitable wet or dry etch to extend each of the backside middle-of-the-line contact openings 142a and 142b. FIG. 16B further shows that a portion of the semiconductor layer 106 is removed in the backside middle-of-the-line contact opening 142b using any suitable wet or dry etch.

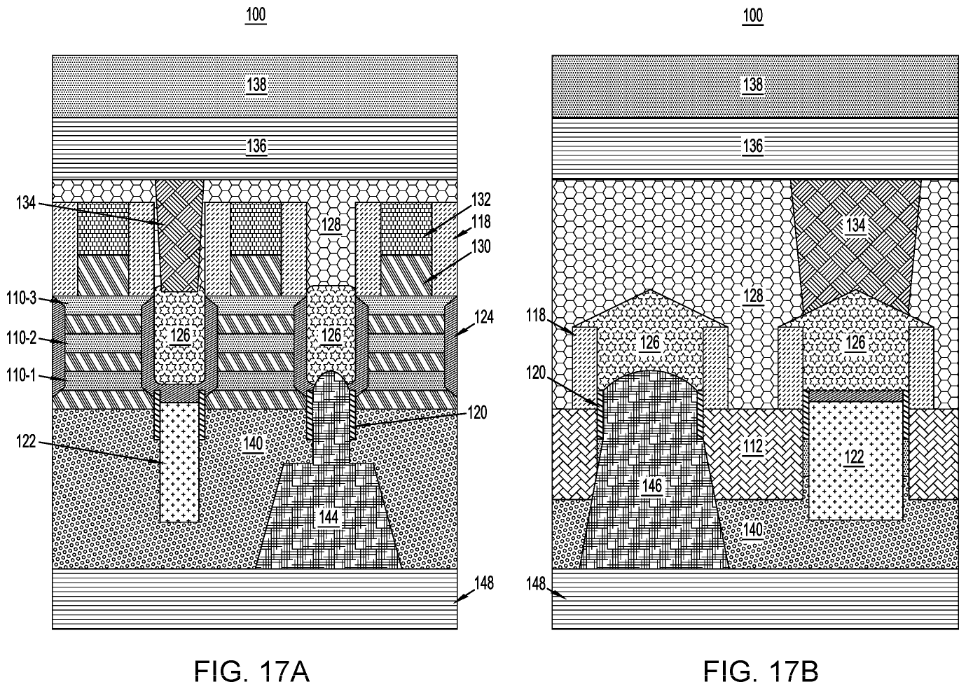

Referring now to FIGS. 17A and 17B, the semiconductor structure 100 is shown following formation of backside middle-of-the-line contacts and a backside interconnect, according to an embodiment of the invention. Backside middle-of-the-line contacts 144 and 146 (also referred to as backside source/drain contact 144 and backside source/drain contact 146) are formed by depositing a suitable conductive metal in the backside middle-of-the-line contact openings 142a and 142b, followed by CMP to remove any metal on top of the backside ILD layer 140. A suitable conductive metal can be deposited in a similar manner and of similar conductive metal as the frontside source/drain contacts 134.

Next, a backside interconnect 148 is formed over the structure including the backside middle-of-the-line contacts 144 and 146 and is based on creation of a wiring scheme that is disposed on both sides of the device layer (front end of line structure).

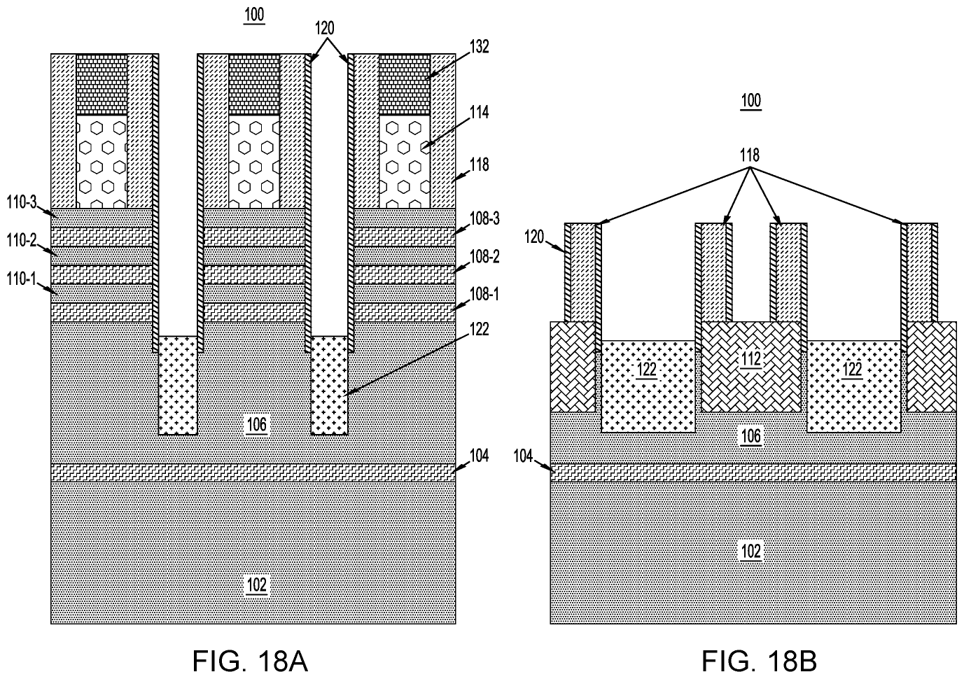

FIGS. 18A-20B show the semiconductor structure 100 starting from FIGS. 5A and 5B illustrating an alternative non-limiting illustrative embodiment. Referring now to FIGS. 18A and 18B, the semiconductor structure 100 is shown following formation of the sacrificial placeholder layer 122, according to an embodiment of the invention. The sacrificial placeholder layer 122 is formed in the recessed area of the semiconductor layer 106 and on a portion of the protecting liner layer 120 using conventional deposition techniques such as ALD, CVD, PVD, etc. The sacrificial placeholder layer 122 may be formed of a sacrificial material as discussed above. FIG. 18A further shows that the sacrificial placeholder layer 122 is formed having a top surface below a bottom surface of the bottom-most sacrificial layer 108-1.

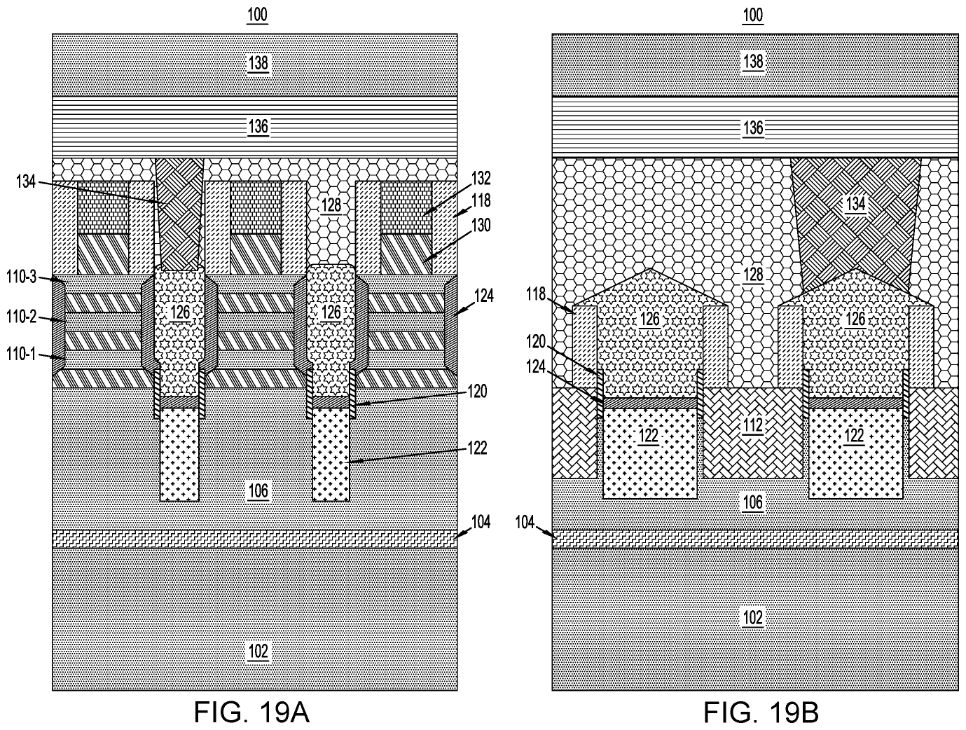

Referring now to FIGS. 19A and 19B, the semiconductor structure 100 is shown following frontside processing, according to an embodiment of the invention. For example, the semiconductor structure 100 shows frontside formation of the source/drain liner layer 124, the source/drain regions 126, the ILD layer 128, the replacement gate structure 130, the dielectric gate cap 132, the frontside BEOL interconnect 136 and the carrier wafer 138. The frontside formation can be carried out as discussed above.

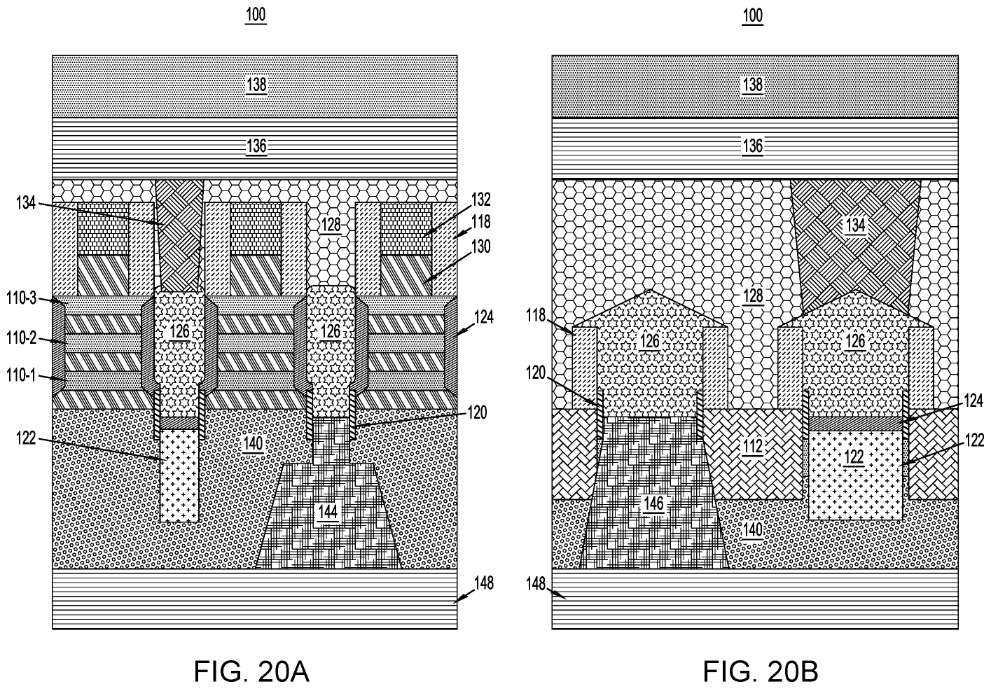

Referring now to FIGS. 20A and 20B, the semiconductor structure 100 is shown following backside processing, according to an embodiment of the invention. For example, the semiconductor structure 100 can be flipped over as discussed above to carry out the backside processing. The semiconductor structure 100 shows backside formation of formation of the backside ILD layer 140, the backside source/drain contacts 144 and 146 and the backside interconnect 148. The backside formation can be carried out as discussed above.

According to an aspect of the invention, a semiconductor structure includes:
a plurality of nanosheet channel layers, wherein the plurality of nanosheet channel layers define a channel region,
a gate structure on the channel region,
a source/drain liner layer disposed on sidewalls of the plurality of nanosheet channel layers and the gate structure,
a source/drain region disposed on the source/drain liner layer, wherein a bottom portion of the source/drain region extends into a backside interlevel dielectric layer, and
a backside contact connected to the bottom portion of the source/drain region,
wherein the bottom portion of the source/drain region is isolated from the gate structure by the source/drain liner layer and a protecting liner layer arranged between the gate structure and the bottom portion of the source/drain region.

The semiconductor structure of the illustrative embodiment advantageously uses a source/drain liner layer and a protecting liner layer to isolate a bottom portion of a source/drain region from a gate structure in a channel portion. This, in turn, avoids the use of an inner spacer, and is compatible with the backside contact formation.

In some embodiments, a bottom portion of the gate structure has tapered sides.

In some embodiments, a bottom portion of the gate structure has a trapezoid configuration.

In one or more additional illustrative embodiments, as may be combined with the preceding paragraphs, a top surface of the backside contact is below a bottom surface of the gate structure.

In one or more additional illustrative embodiments, as may be combined with the preceding paragraphs, the plurality of nanosheet channel layers includes a top-most nanosheet channel layer and a bottom-most nanosheet channel layer, and wherein a top surface of the protecting liner layer is below a bottom surface of the bottom-most nanosheet channel layer.

In one or more additional illustrative embodiments, as may be combined with the preceding paragraphs, the source/drain liner layer includes silicon.

In one or more additional illustrative embodiments, as may be combined with the preceding paragraphs, the protecting liner layer includes a nitride material.

In one or more additional illustrative embodiments, as may be combined with the preceding paragraphs, the protecting liner layer is further arranged between the backside interlevel dielectric layer and the backside contact.

According to another aspect of the invention, a semiconductor structure includes:
a plurality of nanosheet channel layers, wherein the plurality of nanosheet channel layers define a channel region,
a gate structure on the channel region,
a source/drain liner layer disposed on sidewalls of the plurality of nanosheet channel layers and the gate structure,
a source/drain region disposed on the source/drain liner layer, and
a backside contact connected to a bottom portion of the source/drain region,
wherein the bottom portion of the source/drain region is isolated from the gate structure by the source/drain liner layer and a protecting liner layer arranged between the gate structure and the source/drain liner layer.

The semiconductor structure of the illustrative embodiment advantageously uses a source/drain liner layer and a protecting liner layer to isolate a bottom portion of a source/drain region from a gate structure in a channel portion. This, in turn, avoids the use of an inner spacer, and is compatible with the backside contact formation.

In some embodiments, a bottom portion of the gate structure has tapered sides.

In some embodiments, a bottom portion of the gate structure has a trapezoid configuration.

In one or more additional illustrative embodiments, as may be combined with the preceding paragraphs, a top surface of the backside contact is below a bottom surface of the gate structure.

In one or more additional illustrative embodiments, as may be combined with the preceding paragraphs, a top surface of the backside contact is above a bottom surface of the gate structure.

In one or more additional illustrative embodiments, as may be combined with the preceding paragraphs, the plurality of nanosheet channel layers includes a top-most nanosheet channel layer and a bottom-most nanosheet channel layer, and wherein a top surface of the protecting liner layer is below a bottom surface of the bottom-most nanosheet channel layer.

In one or more additional illustrative embodiments, as may be combined with the preceding paragraphs, a bottom surface of the source/drain region is above the bottom surface of the bottom-most nanosheet channel layer.

In one or more additional illustrative embodiments, as may be combined with the preceding paragraphs, the source/drain liner layer includes silicon.

In one or more additional illustrative embodiments, as may be combined with the preceding paragraphs, the protecting liner layer includes a nitride material.

In one or more additional illustrative embodiments, as may be combined with the preceding paragraphs, the protecting liner layer is further arranged between the bottom portion of the gate structure and backside contact.

According to yet another aspect of the invention, a semiconductor structure includes:
a first nanosheet device including:
a first gate structure on a first channel region, and
a first source/drain liner layer disposed on sidewalls of the first gate structure,
a second nanosheet device adjacent the first nanosheet device, the second nanosheet device including:
a second gate structure on a second channel region, and
a second source/drain liner layer disposed on sidewalls of the second gate structure,
a source/drain region disposed between opposing sidewalls of the first source/drain liner layer and the second source/drain liner layer, and
a backside contact connected to a bottom portion of the source/drain region,
wherein the bottom portion of the source/drain region is isolated from the first gate structure by the first source/drain liner layer and a first protecting liner layer arranged between the first gate structure and the first source/drain liner layer, and
wherein the bottom portion of the source/drain region is isolated from the second gate structure by the second source/drain liner layer and a second protecting liner layer arranged between the second gate structure and the second source/drain liner layer.

The semiconductor structure of the illustrative embodiment advantageously uses a source/drain liner layer and a protecting liner layer to isolate a bottom portion of a source/drain region from a gate structure in a channel portion. This, in turn, avoids the use of an inner spacer, and is compatible with the backside contact formation.

In some embodiments, a bottom portion of the first gate structure and a bottom portion of the second gate structure each have a trapezoid configuration.

In one or more additional illustrative embodiments, as may be combined with the preceding paragraphs, a top surface of the backside contact is below a bottom surface of the first gate structure and a bottom surface of the second gate structure.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a plurality of nanosheet channel layers, wherein the plurality of nanosheet channel layers define a channel region;
a gate structure on the channel region;
a source/drain liner layer disposed on sidewalls of the plurality of nanosheet channel layers and the gate structure;
a source/drain region disposed on the source/drain liner layer, wherein a bottom portion of the source/drain region extends into a backside interlevel dielectric layer; and
a backside contact connected to the bottom portion of the source/drain region;
wherein the bottom portion of the source/drain region is isolated from the gate structure by the source/drain liner layer and a protecting liner layer arranged between the gate structure and the bottom portion of the source/drain region.

2. The semiconductor structure according to claim 1, wherein a bottom portion of the gate structure has tapered sides.

3. The semiconductor structure according to claim 1, wherein a bottom portion of the gate structure has a trapezoid configuration.

4. The semiconductor structure according to claim 1, wherein a top surface of the backside contact is below a bottom surface of the gate structure.

5. The semiconductor structure according to claim 1, wherein the plurality of nanosheet channel layers comprises a top-most nanosheet channel layer and a bottom-most nanosheet channel layer, and wherein a top surface of the protecting liner layer is below a bottom surface of the bottom-most nanosheet channel layer.

6. The semiconductor structure according to claim 1, wherein the source/drain liner layer comprises silicon.

7. The semiconductor structure according to claim 1, wherein the protecting liner layer comprises a nitride material.

8. The semiconductor structure according to claim 1, wherein the protecting liner layer is further arranged between the backside interlevel dielectric layer and the backside contact.

9. A semiconductor structure, comprising:
a plurality of nanosheet channel layers, wherein the plurality of nanosheet channel layers define a channel region;
a gate structure on the channel region;
a source/drain liner layer disposed on sidewalls of the plurality of nanosheet channel layers and the gate structure;
a source/drain region disposed on the source/drain liner layer; and
a backside contact connected to a bottom portion of the source/drain region;
wherein the bottom portion of the source/drain region is isolated from the gate structure by the source/drain liner layer and a protecting liner layer arranged between the gate structure and the source/drain liner layer.

10. The semiconductor structure according to claim 9, wherein a bottom portion of the gate structure has tapered sides.

11. The semiconductor structure according to claim 9, wherein a bottom portion of the gate structure has a trapezoid configuration.

12. The semiconductor structure according to claim 9, wherein a top surface of the backside contact is above a bottom surface of the gate structure.

13. The semiconductor structure according to claim 9, wherein the plurality of nanosheet channel layers comprises a top-most nanosheet channel layer and a bottom-most nanosheet channel layer, and wherein a top surface of the protecting liner layer is below a bottom surface of the bottom-most nanosheet channel layer.

14. The semiconductor structure according to claim 13, wherein a bottom surface of the source/drain region is above the bottom surface of the bottom-most nanosheet channel layer.

15. The semiconductor structure according to claim 9, wherein the source/drain liner layer comprises silicon.

16. The semiconductor structure according to claim 9, wherein the protecting liner layer comprises a nitride material.

17. The semiconductor structure according to claim 9, wherein the protecting liner layer is further arranged between the bottom portion of the gate structure and backside contact.

18. A semiconductor structure, comprising:
a first nanosheet device comprising:
a first gate structure on a first channel region; and
a first source/drain liner layer disposed on sidewalls of the first gate structure;
a second nanosheet device adjacent the first nanosheet device, the second nanosheet device comprising:
a second gate structure on a second channel region; and
a second source/drain liner layer disposed on sidewalls of the second gate structure;
a source/drain region disposed between opposing sidewalls of the first source/drain liner layer and the second source/drain liner layer; and
a backside contact connected to a bottom portion of the source/drain region;
wherein the bottom portion of the source/drain region is isolated from the first gate structure by the first source/drain liner layer and a first protecting liner layer arranged between the first gate structure and the first source/drain liner layer; and
wherein the bottom portion of the source/drain region is isolated from the second gate structure by the second source/drain liner layer and a second protecting liner layer arranged between the second gate structure and the second source/drain liner layer.

19. The semiconductor structure according to claim 18, wherein a bottom portion of the first gate structure and a bottom portion of the second gate structure each have a trapezoid configuration.

20. The semiconductor structure according to claim 18, wherein a top surface of the backside contact is below a bottom surface of the first gate structure and a bottom surface of the second gate structure.
